(19) United States
(12) Patent Application Publication
(10) Pub. No.: US 2002/0000572 A1
(43) Pub. Date: Jan. 3, 2002

(54) Soft recovery diode

(76) Inventors: Saburo Okumura, Hyogo-ken (JP); Yasuo Doe, Osaka-fu (JP)

Correspondence Address: WILLIAM H. MURRAY, DUANE MORRIS & HECKSCHER LLP, ONE LIBERTY PLACE, PHILADELPHIA, PA, 19103-7396, US

(21) Appl. No.: 09/875,113

(22) Filed: Jun. 6, 2001

(30) Foreign Application Priority Data
Jun. 30, 2000 (JP) 2000-199179

(51) Int. Cl. H01L 27/15; H01L 31/12; H01L 31/109

(52) U.S. Cl. 257/196; 257/79; 257/106; 257/173

(57) ABSTRACT

A soft recovery diode of the invention includes a first semiconductor layer having N type conductivity. A second N-type semiconductor layer is disposed on the first semiconductor layer and has a lower impurity concentration than the first semiconductor layer. In the surface of the second semiconductor layer opposite to the surface contacting the first semiconductor layer, a plurality of spaced-apart first metallic layers are formed. A second metallic layer is disposed on the first metallic layers and/or the exposed portions of the second semiconductor layer. The first and second metallic layers provide barriers of different heights.

This invention relate to a soft recovery diode.

### BACKGROUND OF THE INVENTION

Fast operating diodes are widely used in power electronics circuits. For example, there is a DC power supply apparatus which converts a DC voltage obtained by rectifying a commercial AC voltage into a high-frequency voltage in an inverter. The high-frequency voltage is voltage-transformed by a transformer before it is rectified in an output-side rectifier. The resulting DC voltage is applied to a load, e.g. a communication apparatus or a welder, which requires more or less higher DC power. Fast operating diodes may be used in the output-side rectifier of the power supply apparatus of the described type. A diode for use in such output-side rectifier desirably should have a short time during which a reverse recovery current flows after forward-biasing of the diode is switched to reverse-biasing. In other words, such diode should have a prompt recovery characteristic for reducing noise and preventing surge.

FIG. 1 shows an example of prior art prompt-recovery characteristic diodes. The diode shown in FIG. 1 includes a first high-concentration N-type semiconductor layer, e.g. an N-type semiconductor substrate 2, having an impurity concentration of, e.g. 10¹⁸/cm³. The thickness of the semiconductor substrate 2 is from 250 μm to 400 μm, for example. A second N-type semiconductor layer 4 is epitaxially grown on one of the major surfaces of the substrate 2. The second N-type layer 4 is a high-concentration, thin layer having a doping concentration of 10¹⁵/cm³ and having a thickness of about 5 μm. Over the second N-type semiconductor layer 4, a third N-type semiconductor layer 6 is epitaxially grown. The third layer 6 has a impurity concentration of, for example, 10¹⁴/cm³ and has a thickness of, for example, about 50 μm. A P-type impurity is diffused into the third N-type layer 6 through its surface to thereby change part of the third N-type layer 6 into a P-type semiconductor layer 8 having an impurity concentration of, for example, 10¹⁸/cm³ and having a thickness of, for example, about 10 μm. Lattice defects are formed in the remaining third N-type semiconductor layer 6 by, for example, doping it with a heavy metal, e.g. gold or platinum, or by irradiating the layer 6 with an electron beam. A cathode electrode 10 and an anode electrode 12 are formed on the exposed surfaces of the substrate 2 and the P-type layer 8, respectively, by evaporating, e.g. aluminum.

Let it be assumed that the forward-biased diode of FIG. 1 having its anode 12 placed at a positive potential and having its cathode 10 placed at a negative potential is switched to the reverse-biased condition in which the anode 12 is placed at a negative potential with the cathode 10 being at a positive potential. Holes emitted from the P-type layer 8 in the forward biased state are absorbed by the lattice defects in the third N-type semiconductor layer 6 when the diode is reverse-biased. As a result, current I flowing in the diode rapidly decreases as shown in FIG. 2, and a depletion layer tends to extend in the third N-type layer 6 toward the second N-type layer 4. Since the concentration of the second N-type layer 4 is higher than that of the third N-type layer 6, the depletion layer cannot extend into the second N-type layer 4.

Accordingly, some holes in the second semiconductor layer 4 remain as residual carriers even after the current I reaches its maximum reverse recovery current value Iᵣᵣ shown in FIG. 2. The residual holes are gradually absorbed into the cathode 10, so that the reverse recovery current gradually decreases after it reaches the maximum reverse recovery current value of Iᵣᵣ. Then, the voltage V across the diode gradually recovers its nominal value as shown in FIG. 2, and no large oscillations are induced in the voltage V, resulting in reduced noise and no surge.

Two of the semiconductor layers, namely, the second and third semiconductor layers 4 and 6, of the above-described diode are epitaxially grown. Accordingly, the manufacturing cost is about 1.5 times that of a diode with only one epitaxially grown layer. Furthermore, the manufacture of this type of diode requires doping or electron beam radiation and, therefore, is relatively troublesome. Another problem is increase of a voltage drop V_{F} across the PN junction formed between the P-type layer 8 and the third N-type layer 6. Soft recovery can be attained for a diode having a reverse breakdown voltage of 600 V or higher. However, it cannot be attained for a diode having a reverse breakdown voltage of, for example, 400 V or lower. This is because the thickness of the third semiconductor layer 6 is thinner than that of the third layer of a higher reverse breakdown voltage diode, which results in less residual holes or carriers, resulting, in turn, in the current rapidly recovering its nominal value after it reaches the maximum reverse recovery current Iᵣᵣ.

Diodes useable in low-voltage circuitry include a Schottky-barrier diode. An example of Schottky barrier diode is shown in FIG. 3. The Schottky barrier diode shown in FIG. 3 includes a first, high impurity concentration, N-type semiconductor layer or substrate 14 having a concentration of, for example, 10¹⁸/cm³. The substrate 14 has a thickness of from about 250 μm to about 400 μm. On the top surface of the substrate 14, a second, low impurity concentration, second N-type layer 16 having a concentration of, for example, 10¹⁴/cm³ is epitaxially grown to a thickness of about 10 μm. A Schottky barrier metal layer 18 is formed over the top surface of the second N-type layer 16 by evaporation or sputtering of a metal, e.g. molybdenum, tungsten, chromium or titanium. A cathode electrode 20 is formed on the exposed (bottom) surface of the substrate 14, and an anode electrode 22 is formed on the top surface of the Schottky barrier metallic layer 18. The electrodes may be formed by evaporating, sputtering or plating a metal, for example, aluminum or nickel.

When the Schottky barrier diode is forward biased with a positive potential applied to the anode 22 and with a negative potential applied to the cathode 20, only the majority carriers, electrons, in the portion of the second N-type layer 16 near the substrate 14 act as carriers in the layer 16. The carrier density in the second N-type layer 16 in the forward-biasing condition is shown in FIG. 4. As represented by a curve to in FIG. 4, the carrier density is lower in the region closer to the anode 22 and is higher in the region closer to the cathode 20.

When the diode is switched from the forward-biasing condition to the reverse-biasing condition, where a negative potential is placed on the anode 22 and a positive potential is on the cathode 20, a depletion layer extends from the portion of the second N-type semiconductor layer 16 adjacent to the Schottky barrier metal layer 18 as indicated by a line t₁ in FIG. 4. The carrier density as a whole is lower than the density to in the forward-biasing condition. The length of the depletion layer when the maximum reverse recovery current is flowing is L1. In the reverse-biasing condition, residual carriers are present in a region in the vicinity of the substrate 14 as indicated by shading in FIG. 4. The residual carriers are gradually attracted toward the cathode 20, which provides the diode with a gradual recovery characteristic. The reverse breakdown voltage of Schottky barrier diodes of this type is 60 V at the highest or lower.

Therefore, an object of the present invention is to provide low-cost, fast, high reverse breakdown voltage, soft recovery diodes.

### SUMMARY OF THE INVENTION

A soft recovery diode according to the present invention has a first semiconductor layer of one conductivity type. A second semiconductor layer of the same conductivity type as the first semiconductor layer is disposed on and in contact with one of the two opposing major surfaces of the first semiconductor layer. The second layer has a lower impurity concentration than the first layer. A plurality of mutually spaced first metallic layers are disposed in one of the opposing major surfaces of the second semiconductor layer opposite to said first semiconductor layer. A second metallic layer is disposed on at least those portions of the one surface of the second semiconductor layer in which the first metallic layers are not disposed. The first and second metallic layers provide barriers of different heights. The barrier provided by the first metallic layers may be higher than the barrier provided by the second metallic layer. Conversely, the barrier formed by the second metallic layer may be higher than the barrier formed by the first metallic layers.

When the soft recovery diode of the above-described arrangement is forward biased, majority carriers in the first semiconductor layer provide carriers for the second semiconductor layer in those portions located between the first semiconductor layer and the metallic layer providing a low barrier. Accordingly, the closer to the first semiconductor layer, the higher the carrier density is in the second semiconductor layer, and the closer to the first and second metallic layers, the carrier density is lower. On the other hand, into the regions of the second semiconductor layer between the first semiconductor layer and the metallic layer providing a higher barrier, minority carriers are injected from the higher-barrier providing metallic layer, and, therefore, the closer to the higher-barrier providing layer, the carrier density is higher, and the closer to the first semiconductor layer, the carrier density is lower.

When the diode is switched from the forward-biasing condition to the reverse-biasing condition, a depletion layer expands in the second semiconductor layer from the region adjacent to the lower-barrier providing metallic layer. After the reverse current reaches the maximum reverse recovery current value, the residual carriers are gradually attracted toward the first semiconductor layer. In contrast, the minority carriers injected from the higher-potential-barrier providing metallic layer recombine with the majority carriers injected from the first semiconductor layer, resulting in extending of the depletion layer toward the first semiconductor layer. When the reverse current reaches the maximum reverse recovery current, there are no minority carriers around the first semiconductor layer, and, therefore, once the maximum reverse recovery current is attained, the reverse current promptly decreases to zero. In other words, a faster reverse recovery characteristic is realized beneath the higher-barrier metallic layer, while the reverse recovery is gradual beneath the lower-barrier metallic layer.

The total area of those portions of the first metallic layers which are in contact with the second semiconductor layer may be larger than the total area of the portions of the second metallic layer contacting the second semiconductor layer. Conversely, the total area of the second metallic layer portions contacting the second semiconductor layer may be larger than the total area of those portions of the first metallic layers which are in contact with the second semiconductor layer. In other words, the total area of the higher-barrier providing metallic layer contacting the second semiconductor layer may be larger or smaller than the total area of the lower-barrier providing metallic layers contacting the second semiconductor layer. Then, if the total area of the high-barrier providing layer portions contacting the second semiconductor layer is larger, a resulting diode exhibit relatively fast recovery and has a high breakdown voltage, and, if the total area of the high-barrier providing layer portions contacting the second semiconductor layer is smaller, a resulting diode exhibits soft recovery and has a relatively low breakdown voltage.

### BRIEF DESCRIPTION OF THE DRAWINGS

FIG. 1 is a cross-sectional view of a prior art soft recovery diode;

FIG. 2 shows the voltage and current characteristics of the diode of FIG. 1;

FIG. 3 is a cross-sectional view of a prior art Schottky barrier diode;

FIG. 4 shows the carrier distribution of the Schottky barrier diode of FIG. 3;

FIGS. 5A, 5B, 5C and 5D are cross-sectional views in different manufacturing steps of a soft recovery diode according to one embodiment of the present invention;

FIG. 6 illustrates the carrier distribution of the soft recovery diode manufactured by the process illustrated in FIGS. 5A through 5D; and

FIG. 7 is a cross-sectional view of a modification of the soft recovery diode shown in FIGS. 5A through 5D.

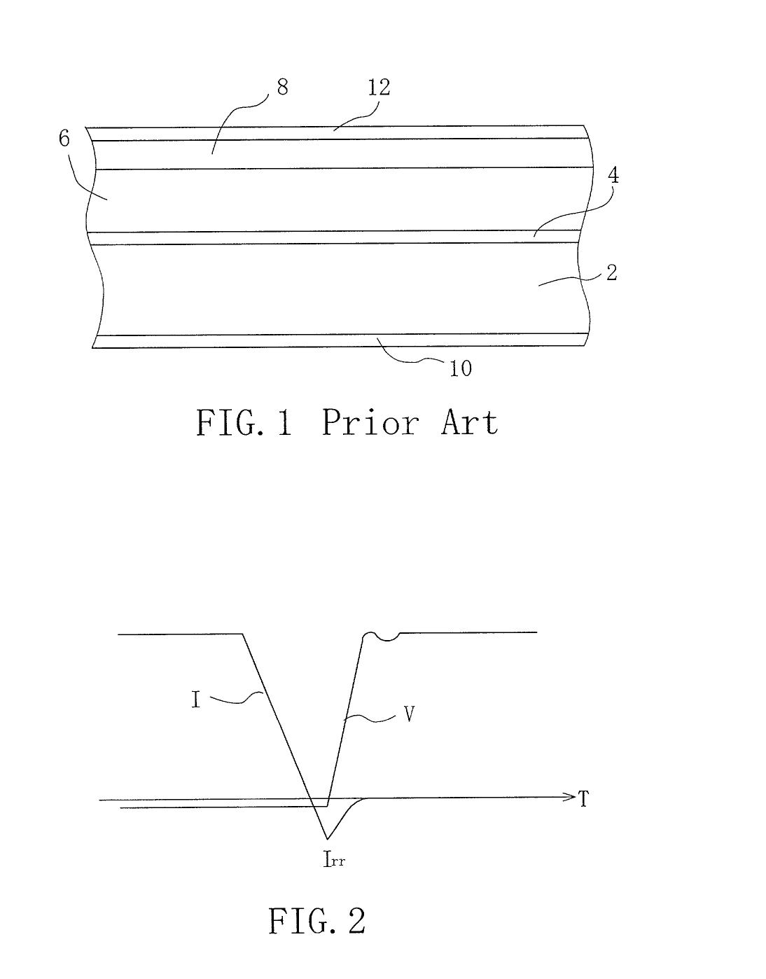

### DETAILED DESCRIPTION OF EMBODIMENTS

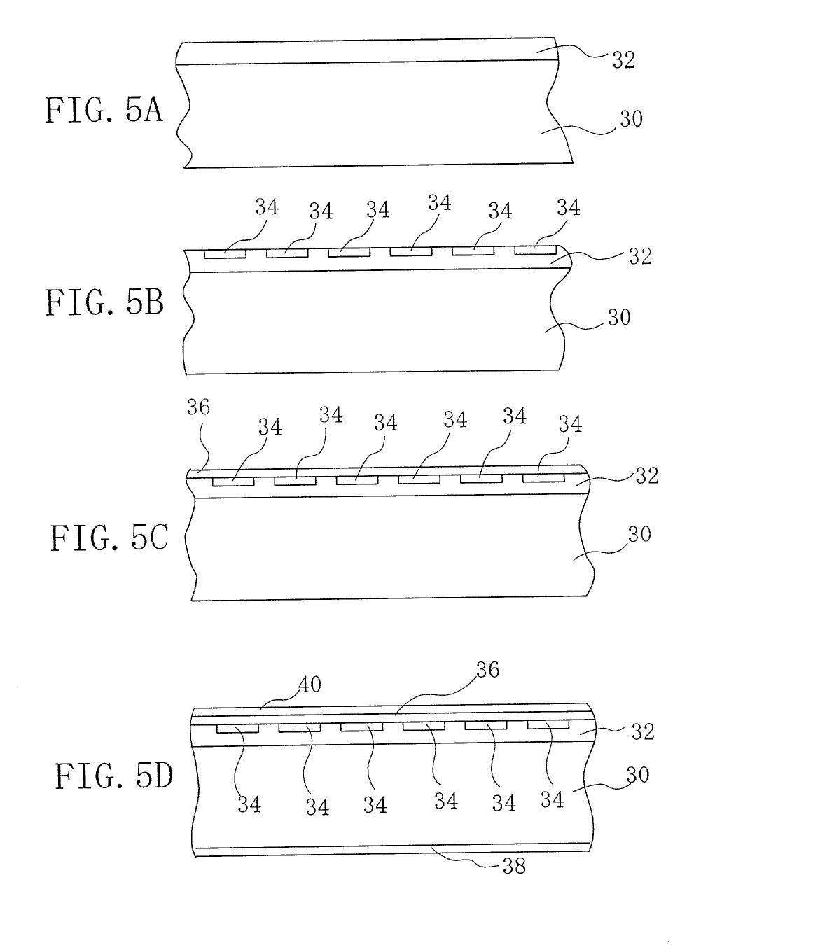

FIG. 5D shows a completed soft recovery diode according to a first embodiment of the present invention. As shown, the soft recovery diode according the first embodiment has a first semiconductor layer, e.g. a semiconductor substrate 30. The substrate 30 is of one conductivity type, e.g. N-type, has a high impurity concentration of, for example, 10¹⁸/cm³, and has a thickness of, for example, between about 250 μm and about 400 μm. A second semiconductor layer 32 is epitaxially grown on one of the major surfaces of the substrate 30. The second layer 32 is of the same conductivity type as the substrate 30, i.e. N-type in the illustrated example, and has an impurity concentration of, for example, 10¹⁴/cm³, which is lower than that of the substrate 30. The thickness of the second layer 32 is, for example, between about 10 μm and about 20 μm, which is smaller than the thickness of the substrate 30.

A plurality of first metallic layers 34 are formed to extend into the second semiconductor layer 32 from its major surface opposite to the substrate 30. The material of the first metallic layers 34 is a metal forming a high barrier with the second layer 32. The metal of the first metallic layers 34 may be, for example, platinum which can form a barrier as high as 0.8 eV. The thickness of the first metallic layers 34, i.e. the depth to which the first metallic layers 34 extend into the second semiconductor layer 32, is, for example, about 0.01 μm. The first metallic layers 34 are spaced from each other by a predetermined spacing.

A second metallic layer 36 is disposed on the surface of the second semiconductor layer 32 in which the first metallic layers 34 are formed, so that the exposed surface of the second layer 32 and the exposed surfaces of the first metallic layers 34 are covered by the second metallic layer 36.

The metal of the second metallic layer 36 is a metal which can form a relatively low barrier of a height of, for example, between 0.6 eV and 0.7 eV with respect to semiconductor. Such metal may be molybdenum, tungsten, chromium or titanium. The second metallic layer 36 provides a Schottky barrier metallic layer.

A cathode electrode layer 38 is disposed on the major surface of the substrate 30 opposite to the second semiconductor layer 32. An anode electrode layer 40 is disposed on the surface of the second metallic layer 36 opposite to said second semiconductor layer 32.

This soft recovery diode may be manufactured in a following manner.

First, as shown in FIG. 5A, on one of the two opposing major surfaces of the semiconductor substrate 30, the second semiconductor layer 32 is disposed by epitaxial growing. Then, an oxide film is disposed on the surface of the second semiconductor layer 32 opposite to the substrate 30, and openings are formed in the oxide film at locations where the first metallic layers 34 are to be formed. Platinum is, then, evaporated or sputtered onto the assembly including the substrate 30, the second semiconductor layer 32 and the oxide film with openings formed therein, and, thereafter, the assembly is heated to embed the evaporated or sputtered platinum into the second semiconductor layer 32, which results in the first metallic layers 34 embedded in the second semiconductor layer 32. After that, the oxide film and the metal adhering to the surface of the exposed surface portions of the second semiconductor layer 32 are removed. Then, the exposed surface portions of the second semiconductor layer 32 and the surfaces of the first metallic layers 34 are leveled off. See FIG. 5B.

After that, as shown in FIG. 5C, the second metal is evaporated or sputtered onto the leveled surfaces of the semiconductor layer 32 and the first metallic layers 34 to dispose the second metallic layer 36.

After that, the cathode and anode electrode layers 38 and 40, respectively, of a metal, for example, aluminum or nickel, are disposed on the major surface of the substrate 30 opposite to the second semiconductor layer 32 and on the exposed major surface of the second metallic layer 36, respectively, by evaporation, sputtering or plating, to complete the diode shown in FIG. 5D.

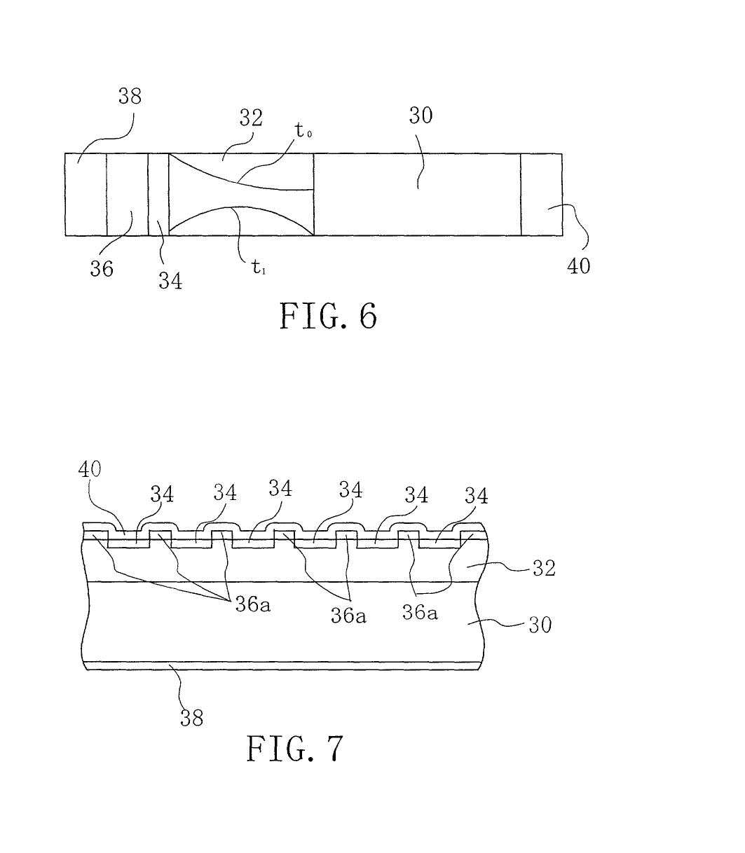

When the Schottky barrier diode of the above-described arrangement is forward biased by placing a positive potential on the anode electrode 40 and a negative potential on the cathode electrode 38, electrons or majority carriers from the semiconductor substrate 30 are distributed in those portions of the second semiconductor layer 32 between those portions of the second metallic layer 36 which are not in contact with the first metallic layers 34 and the semiconductor substrate 30. Since the first metallic layers 34 form a high barrier, minority carriers, i.e. holes, are injected from the first metallic layers 34 into the second semiconductor layer 32. Then, the carrier distribution as represented by a line to in FIG. 6 is produced in the second semiconductor layer 32 between each of the first metallic layers 34 and the semiconductor substrate 30, in which the carrier density is higher in the portion closer to the first metallic layer 34 and decreases toward the substrate 30.

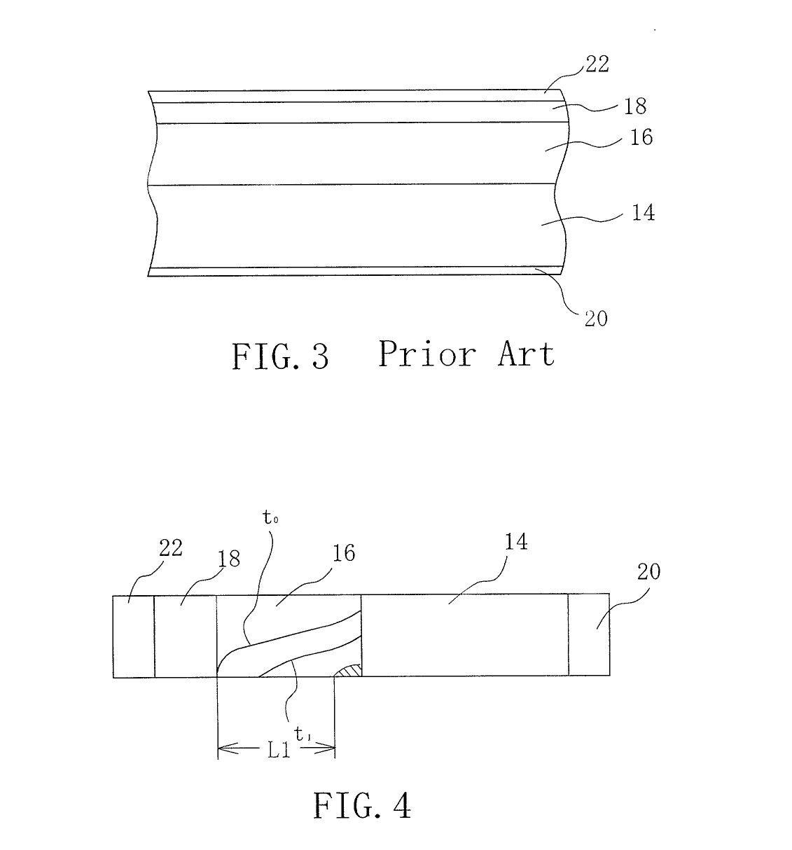

When the above-described forward-biased diode is switched to a reverse-biased condition, by applying a negative voltage to the anode electrode 40 and a positive potential to the cathode electrode 38, a depletion layer extends from the second metallic layer 36 side toward the semiconductor substrate 30 side in the portions of the second semiconductor layer 32 between the portions of the second metallic layer 36 which are not in contact with the first metallic layers 34 and the substrate 30, for a reason similar to the one described with reference to FIGS. 3 and 4. After the maximum reverse recovery current Iᵣᵣ flows, the residual carriers gradually move into the semiconductor substrate 30, so that the current becomes zero. The holes injected from the first metallic layers 34 recombine with the electrons injected from the substrate 30 to disappear, and the depletion layer extends toward the substrate 30. When the reverse current reaches its maximum reverse recovery current value, there are no residual holes in the portion of the second semiconductor layer 32 near the substrate 30 as is seen from a carrier distribution curve to in FIG. 6, and, therefore, the current rapidly reaches zero.

As described above, in the portions of the second semiconductor layer 32 beneath the first metallic layers 34, a fast reverse recovery characteristic is realized, while, in the portions of the layer 32 directly contacting the second metallic layer 36 with no intervening first metallic layers 34, gradual recovery takes place.

With the total area of the portions of the first metallic layers 34 contacting the second semiconductor layer 32 being greater than the total area of the portions of the second metallic layer 36 which are not in contact with the first metallic layer 34, a diode with a relatively fast recovery and with a high breakdown voltage, e.g. 400 V, results. On the other hand, if the total area of the portions of the first metallic layers 34 contacting the second semiconductor layer 32 is smaller than that of the portions of the second metallic layer 36 which are not in contact with the first metallic layers 34, the diode exhibits a soft recovery characteristic and has a high breakdown voltage of, e.g. 200 V, which is high relative to a prior art Schottky barrier diode.

In the above-described embodiment, a high barrier providing metal, platinum, is used for the first metallic layers 34 and a low barrier metal for the second metallic layer 36. Instead, a low barrier metal may be used for the first metallic layers 34 with a high barrier metal used for the second metallic layer 36.

In the above-described embodiment, the second metallic layer 36 is disposed to overlie both the top surfaces of the first metallic layers 34 and the exposed top surface portions of the second semiconductor layer 32, but second metallic layers 36a may be disposed only on the exposed top surface portions of the second semiconductor layer 32 where the fist metallic layers 34 are not disposed, as shown in FIG. 7. The second metallic layers 35a are formed of a metal providing a low barrier, such as molybdenum, tungsten or chromium. After that, the anode electrode layer 40 is disposed to overlie the first metallic layers 34 and the second metallic layers 35a. In this modification, too, the first metallic layers 34 may be of a lower-barrier forming metal with the second metallic layer 35a formed of a higher-barrier forming metal.

What is claimed is:

1. A soft recovery diode comprising:
a first semiconductor layer of one conductivity type;
a second semiconductor layer of the same conductivity type as said first semiconductor layer having two opposing major surfaces with one major surface contacting said first semiconductor layer and having a lower impurity concentration than said first semiconductor layer;
a plurality of mutually spaced first metallic layers formed in the other of said opposing major surfaces of said second semiconductor layer, said first metallic layers contacting said second semiconductor layer; and
a second metallic layer disposed to contact at least said other major surface of said second semiconductor layer;
said first and second metallic layers providing barriers of different heights.

2. The soft recovery diode according to claim 1 wherein said first metallic layers provide a higher barrier than said second metallic layer.

3. The soft recovery diode according to claim 1 wherein said second metallic layer provides a higher barrier than said first metallic layers.

4. The soft recovery diode according to claim l wherein a total area of those portions of said first metallic layers which are in contact with said second semiconductor layer is larger than a total area of those portions of said second metallic layer which are in contact with said second semiconductor layer.

5. The soft recovery diode according to claim 1 wherein a total area of those portions of said second metallic layer which are in contact with said second semiconductor layer is larger than a total area of those portions of said first metallic layers which are in contact with said second semiconductor layer.
